(19) United States
(12) Patent Application Publication
(10) Pub. No.: US 2007/0170812 A1
(43) Pub. Date: Jul. 26, 2007

(54) SYSTEM APPARATUS AND METHODS FOR PROCESSING SUBSTRATES USING ACOUSTIC ENERGY

(76) Inventors: Pejman Fani, San Diego, CA (US); Mark Rouillard, Mission Viejo, CA (US)

Correspondence Address: WOLF, BLOCK, SCHORR & SOLIS-COHEN LLP, 1650 ARCH STREET, 22ND FLOOR, PHILADELPHIA, PA, 19103-2334, US

(21) Appl. No.: 11/625,651

(22) Filed: Jan. 22, 2007

Related U.S. Application Data
(60) Provisional application No. 60/762,827, filed on Jan. 26, 2006.
(60) Provisional application No. 60/760,820, filed on Jan. 20, 2006.
(60) Provisional application No. 60/837,965, filed on Aug. 16, 2006.

(51) Int. Cl. H01L 41/00

(52) U.S. Cl. 310/311

(57) ABSTRACT

A wafer cleaning system having a crystal or ceramic transducer assembly. The transducer assembly is adapted to convert electrical energy into sonic energy. The crystal or ceramic has a first conductive surface. The transducer assembly also has a transmitter made of an inert non-reactive plastic that transmits the sonic energy generated by the crystal or ceramic. The transmitter has a surface bonded directly to the conductive surface of the crystal or ceramic.

### CROSS-REFERENCE TO RELATED APPLICATIONS

The present application claims the benefit of U.S. Provisional Application Ser. No. 60/762,827, filed Jan. 26, 2006, U.S. Provisional Application Ser. No. 60/760,820, filed Jan. 20, 2006, U.S. Provisional Application Ser. No. 60/837,965, filed on Aug. 16, 2006, the entireties of which are hereby incorporated by reference.

### FIELD OF THE INVENTION

The present invention relates generally to the field of processing flat articles and specifically to systems, apparatus and methods for cleaning flat articles, such as semiconductor wafers, utilizing acoustic energy.

### BACKGROUND OF THE INVENTION

In the field of semiconductor manufacturing, it has been recognized in the industry that removing particles from semiconductor wafers during the manufacturing process is a critical requirement to producing quality profitable wafers. While many different systems and methods have been developed over the years to remove particles from semiconductor wafers, many of these systems and methods are undesirable because they cause damage to the wafers. Thus, the removal of particles from wafers must be balanced against the amount of damage caused to the wafers by the cleaning method and/or system. It is therefore desirable for a cleaning method or system to be able to break particles free from the delicate semiconductor wafer without resulting in damage to the device structure.

Existing techniques for freeing small particles from the surface of a semiconductor wafer utilize a combination of chemical and mechanical processes. One typical cleaning chemistry used in the art is standard clean 1 (“SC1”), which is a mixture of ammonium hydroxide, hydrogen peroxide, and water. SC1 oxidizes and etches the surface of the wafer. This etching process, known as undercutting, reduces the physical contact area to which the particle binds to the surface, thus facilitating ease of removal. However, a mechanical process is still required to actually remove the particle from the wafer surface.

For larger particles and for larger devices, scrubbers have been used to physically brush the particle off the surface of the wafer. However, as device sizes shrank in size, scrubbers and other forms of physical cleaners became inadequate because their physical contact with the wafers was causing catastrophic damage to smaller devices.

Recently, the application of acoustical/sonic energy to the wafers during chemical processing has replaced physical scrubbing to effectuate particle removal. The sonic energy used in substrate processing is generated via a source of sonic energy. Typically, this source of sonic energy comprises a transducer which is made of piezoelectric crystal or ceramic. In operation, the transducer is coupled to a power source (i.e., a source of electrical energy). An electrical energy signal (i.e., electricity) is supplied to the transducer. The transducer converts this electrical energy signal into vibrational mechanical energy (i.e. sonic energy) which is then transmitted to the substrate(s) being processed. An example of such an arrangement is illustrated in U.S. Pat. No. 6,679,272 to Bran et al., the entirety of which is incorporated by reference. Characteristics of the electrical energy signal supplied to the transducer from the power source dictate the characteristics of the sonic energy generated by the transducer. For example, increasing the frequency and/or amplitude of the electrical energy signal will increase the frequency and/or amplitude of the sonic energy being generated by the transducer.

A transducer assembly can comprise a transducer used to transmit sonic energy and a transmitter.

In the past, attaching an inert non-reactive plastic transmitter directly to the surface of a transducer, which is generally crystal or ceramic, in order to provide effective transmission of sonic energy was not possible. In order to effectively accomplish this, one must prevent the transmitter from becoming separated from the surface of the crystal or ceramic during the process of transmitting sonic energy through the transmitter. Should separation occur, sonic or acoustic energy will not be efficiently transmitted from the piezoelectric crystal or ceramic transducer through the transmitter to the substrate. Also, portions of the transmitter that become separated from the crystal or ceramic may fall onto or come into contact with the surface of the substrate during substrate processing, thereby contaminating the substrate surface.

Therefore, there is a need in the field of substrate cleaning to effectively provide an inert non-reactive plastic layer directly to the transducer.

In view of the aforementioned deficiencies in coupling transmitters to crystals or ceramics, and in further view of the discovery of the source of these deficiencies, a novel apparatus and method have been invented that eliminate or minimize these deficiencies.

Additionally, existing sonic cleaning systems have other deficiencies in that these systems either damage the delicate devices on the wafers and/or do not apply the acoustic energy uniformly across the wafer's surface. As a result, new and improved transducer assembly arrangements and structures are always needed in the industry.

### SUMMARY OF THE INVENTION

It is therefore an object of the present invention to provide a transducer assembly having a crystal or ceramic transducer that is directly bonded to a transmitter made of inert, non-reactive plastic for transmitting the acoustic energy generated by the crystal or ceramic transducer.

Another object of the present invention to provide a system, apparatus and method of for cleaning flat articles that reduces and/or eliminates the damage caused to the flat article.

Still another object of the present invention is to provide a system, apparatus and method for applying acoustic energy to a substrate in a more uniform and controlled manner.

These and other objects are met by the present invention, which in one aspect can be a transducer assembly for processing substrates comprising: crystal or ceramic adapted to convert electrical energy into sonic energy, the crystal or ceramic having a first conductive surface; and a transmitter made of an inert non-reactive plastic for transmitting sonic energy generated by the crystal or ceramic, the transmitter having a first surface bonded directly to the first conductive surface of the crystal or ceramic.

Another aspect of the invention can be a system for processing a substrate comprising: means for supporting at least one substrate; means for supplying a process fluid to the at least one substrate; and a transducer assembly comprising a crystal or ceramic adapted to convert electrical energy into sonic energy, the crystal or ceramic having a first conductive surface, and a transmitter made of an inert non-reactive plastic for transmitting sonic energy generated by the crystal or ceramic, the transmitter having a first surface bonded directly to the first conductive surface of the crystal or ceramic and a second surface in contact with the process fluid.

Yet another aspect of the invention can be a method for processing a substrate comprising: a) supporting a substrate; b) contacting a first surface of a substrate with a process fluid; c) providing a transducer assembly comprising a crystal or ceramic adapted to convert electrical energy into sonic energy, the crystal or ceramic having a first conductive surface, and a transmitter made of an inert non-reactive plastic for transmitting sonic energy generated by the crystal or ceramic, the transmitter having a first surface bonded directly to the first conductive surface of the crystal or ceramic and a second surface; d) positioning the transducer assembly so that at least a portion of the second surface of the transmitter is in contact with the process fluid; and e) applying an electrical signal to the crystal or ceramic so that sonic energy is created by the crystal or ceramic and transmitted by the transmitter into the process fluid and to the first surface of the substrate.

Still yet another aspect of the invention can be a method of assembling a transducer assembly for processing a substrate, the method comprising: a) providing a crystal or ceramic adapted to convert electrical energy into sonic energy, the crystal or ceramic having a first conductive surface; b) providing a transmitter made of an inert non-reactive plastic for transmitting sonic energy generated by the transducer, the transmitter having a first surface; c) chemically and/or mechanically altering the first surface of the transmitter to increase the cohesion capability of the first surface of the transmitter; and d) bonding the first surface of the transmitter directly to the first conductive surface of the crystal or ceramic directly.

Another aspect of the invention can be a system for processing a flat article comprising: a rotatable support for supporting a flat article; a dispenser for applying a film of liquid onto a surface of a flat article positioned on the support; a tubular transmitter having an outer surface and an inner surface forming a cavity, the tubular transmitter positioned so that a portion of the outer surface of the tubular transmitter contacts the film of liquid formed on the surface of the flat article; at least one transducer positioned in the cavity and bonded to the inner surface of the tubular transmitter; and the at least one transducer adapted to convert electrical energy into acoustic energy that propagates through the tubular transmitter into the film of liquid and to the surface of the flat article.

Yet another aspect of the invention can be a transducer assembly for processing a flat article comprising: a tubular transmitter having an outer surface and an inner surface forming a cavity; and at least one transducer positioned in the cavity and bonded to the inner surface of the tubular transmitter.

Still yet another aspect of the invention can be a method for processing a flat article comprising: a) supporting a flat article; b) contacting a first surface of the flat article with a process fluid; c) providing a transducer assembly comprising a tubular transmitter having an outer surface and an inner surface forming a cavity and at least one transducer positioned in the cavity and bonded to the inner surface of the tubular transmitter; d) positioning the transducer assembly so that a portion of the outer surface of the tubular transmitter is in contact with the process fluid; and e) applying an electrical signal to the transducer so that acoustic energy is created by the transducer and transmitted by the tubular transmitter into the process fluid and to the first surface of the flat article.

These and various other advantages and features of novelty that characterize the invention are pointed out with particularity in the claims annexed hereto and forming a part hereof. However, for a better understanding of the general technology, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

FIG. 1 is a schematic of a transducer assembly according to one embodiment of the present invention.

FIG. 2 is a schematic of a megasonic cleaning system implementing the transducer assembly of FIG. 1 according to one embodiment of the present invention.

FIG. 3 is a schematic of a transducer assembly according to an embodiment of the present invention.

FIG. 4 is a cross-sectional schematic of a megasonic cleaning system implementing the transducer assembly of FIG. 3 according to an embodiment of the present invention.

FIG. 5 is a side view of the transducer assembly of FIG. 3 in cross-section and positioned above a substrate.

FIG. 6 is a perspective view of five alternative embodiments of the transducer assembly, according to the present invention.

### DETAILED DESCRIPTION OF THE INVENTION

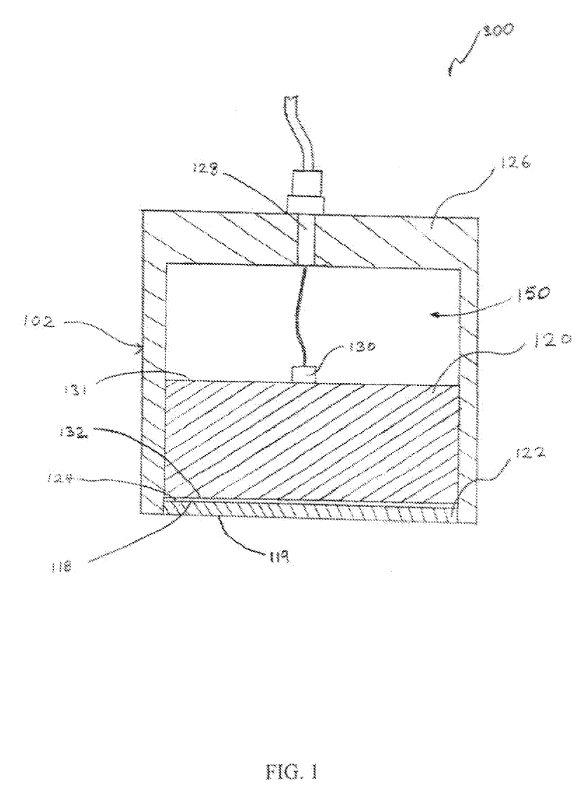

Referring to FIG. 1, a transducer assembly 300 is shown according to one embodiment of the present invention. The transducer assembly 300 comprises a transducer 120 and a transmitter 122. The transducer 120 is made of piezoelectric crystal or ceramic material. The transducer 120 has a top surface 131 and a conductive surface 132. The top surface 131 of the transducer 120 is operably connected to at least one electric connector 130. The electric connector 130 is connected to a power source (not shown). As will be discussed in further detail below, the conductive surface 132 of the transducer 120 is directly bonded to the transmitter 122.

The transducer 120 may be cylindrical in shape and comprised of PVDF (a polymer), PZT (lead zirconate titanate, Pb ZrₓTi₁₋ₓO₃), PMNT (lead magnesium niobate titanate), BT (barium titanate, BaTiO₃), LN (lithium niobate, LiNbO₃), BF (BiFeO3), Quartz (natural or synthetic), Rochelle Salt (a natural substance), LTa (single crystal, lithium tantalite, LiTaO₃), or PMN-PT (single crystal, lead magnesium niobate-lead titanate). However, it should be understood that the transducer 120 is not limited to those materials listed above and can be any suitable crystal, ceramic or other material with piezoelectric properties.

The thickness of the transducer 120 is determined by a variety of factors including but not limited to the frequency of the electrical signal from the electric connector 130. Upon an electrical signal being received by the transducer 120 via the electric connector 130, the electrical signal is converted into acoustic energy corresponding to the frequency and amplitude of the electrical signal. For example, if the electrical signal is varying in a specific pattern as it is received by the transducer 120, the acoustic energy produced by the transducer 120 will have a frequency that correspondingly varies in the same manner. As will be discussed in further detail below, once the acoustic energy is created, it can be transmitted through the transmitter 122 to a substrate or other article to facilitate processing.

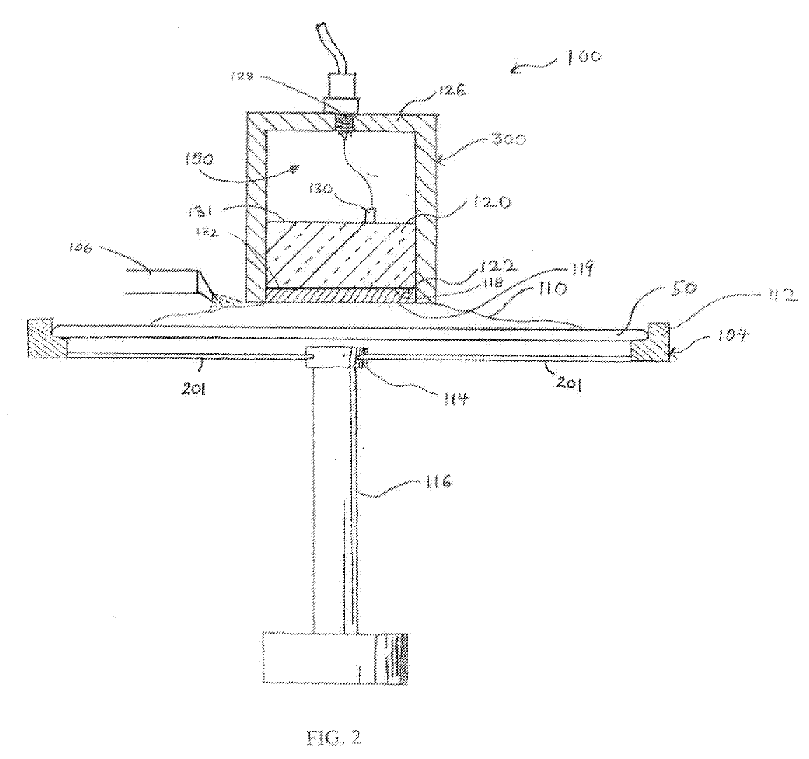

The transmitter 122 may be a flat plate comprising a first surface 118 and a second surface 119. The invention is not limited to the shape discussed above and the transmitter 122 may be a curved or angled plate. Furthermore, the first surface 118 may be flat, while the second surface 119 may be curved or angled, or vice-versa. As will be discussed in further detail below, the first surface 118 of the transmitter 122 is directly bonded to the conductive surface 132 of the transducer 120. The second surface 119 of the transmitter 122 is exposed so as to contact a process fluid 110 (shown in FIG. 2).

The transmitter 122 may be comprised of an inert, non-reactive material, such as plastic. Some of the materials that the transmitter 122 can be comprised of are fluoropolymer (e.g., Teflon®), polypropylene, polyethylene, high density polypropylene, polyvinyl chloride or polyimide. This includes but is not limited to PVDF (a fluoropolymer), PFA (a fluoropolymer), FEP (a fluoropolymer), ETFE (a fluoropolymer), PTFE (a fluoropolymer, which is commonly known as TEFLON), PP (polypropylene), PE (polyethylene), HPE (high density polypropylene), PVC (polyvinylchloride), PI (a polyimide, which is commonly known as Kapton).

The thickness of the transmitter 122 is selected using a variety of factors, preferably, transmitting acoustic energy efficiently without losses and heat buildup, yet providing structural and chemical stability and resistance for the process. The thickness of the transmitter 122 is preferably proportional to the frequency and amplitude of the electrical signal being transmitted through the transducer 120. In one embodiment, the thickness of the transmitter 122 is between about 0.02 and about 0.3 inches. In a preferred embodiment, the thickness of the transmitter 122 is between about 0.03 and about 0.08 inches. Optimally, the axial thickness transmitter 122 should be approximately equal to a fraction of an even number of wavelengths or half wavelengths of the energy to be applied to the wafer.

Direct bonding of the first surface 118 of the transmitter 122 with the conductive surface 132 of the transducer 120 can be achieved in a variety of ways. In one embodiment, the first surface 118 of the transmitter 122 can be bonded directly to the conductive surface 132 of the transducer 120 through use of an adhesive material. The adhesive material may be any suitable adhesive including but not limited to an epoxy-based adhesive (such as Ablestick conductive epoxy) and a cyanoacrylate-based adhesive (such as Loctite Instant Adhesive).

To aid in the bonding process, the first surface 118 of the transmitter 122 can be chemically and/or mechanically altered to increase cohesion between the first surface 118 of the transmitter 122 and the conductive surface 132 of the transducer 120. The first surface 118 of the transmitter 122 can be mechanically altered through scrubbing, abrasion, scraping, scouring, scratching and the like. When the first surface 118 of the transmitter 122 is roughened, the surface area to which the adhesive bonds increases, thereby increasing the strength of the bond. Alternatively, both the conductive surface 132 of the transducer 120 and the first surface 118 of the transmitter 122 may be mechanically or chemically altered.

The first surface 118 of the transmitter 122 may be etched with a gaseous plasma or a liquid-based solution. Etching aids in the bonding process because the first surface 118 of the transmitter 122 is often made from a material the prevents or substantially prevents interaction with other compounds. For example, fluoropolymers are protected from interaction with many compounds and give “nonstick” properties to materials. Although adhesion resistant characteristics are desirable in finished products, it is not desirable when the material must be bonded to the fluoropolymer during manufacturing steps.

Etching replaces the fluorine atoms with functional groups that can anchor a layer of adhesive to the transmitter material. The etching process is a reaction between the sodium in the etchant and the fluorine in the polymer or transmitter material. Sodium in the etching solution strips the fluorine from the carbon backbone by a charged-charge interaction (Na+ to F−) and promotes its replacement with functional groups which are the organic species responsible for adhesion. Such functional groups include but are not limited to a hydroxyl functional group [OH], a carbonyl functional group [C═O] and a carboxyl functional group [COOH]. Chains deprived of fluorine are electron-deficient and readily bond to oxygen and water vapor when the transmitter surface is exposed to air after the etchant process. Areas that have been treated in this way can then be easily bonded to other surfaces. In one embodiment, etching solutions comprise sodium/ammonia solutions including but not limited to TetraEtch®, Bond-Prep®, FluoroEtch®.

After the first surface 118 of the transmitter 122 has been etched, adhesive is applied to either the first surface 118 of the transmitter 122 or the conductive surface 132 of the transducer 120. The first surface 118 of the transmitter 122 is then directly bonded to the conductive surface 132 of the transducer 120.

The thickness of the adhesive material can be any desired thickness that effectively provides for a strong and uniform bond coverage of the surface areas without substantial voids or irregularities. Yet, the adhesive should be thin enough to permit the transfer of energy from the transducer 120 to the transmitter 122 without significant impedance or heat buildup. In other words, the adhesive should preferably have a thickness that does not substantially affect transmission of the acoustic energy from the transducer 120 to the transmitter 122. In a preferred embodiment, bond thickness is between 3 to 7 thousandths of an inch.

In another embodiment, bonding of the transmitter 122 directly to the conductive surface 132 of the transducer 120 can be achieved through thermal fusing of the first surface 118 of the transmitter 122 and the conductive surface 132 of the transducer 120. Alternatively, the conductive surface of the transducer 120 may comprise a metal coating 124 bonded directly to the first surface 118 of the transmitter 122. More specifically, in an embodiment where conductive adhesive is used, metal coating 124 may not be present.

In one embodiment, a housing 126 is connected to the transmitter 122 to form an enclosed space 150. The housing 126 serves to protect the transducer 120 and other components within the enclosed space 150. The invention, is not so limited however, and other means may be used. The housing 126 may be cylindrical in shape. However, the housing 126 is not limited in shape and can be any desired shape including but not limited to square, rectangular or oval. The housing 126 can be made from materials including, but not limited to, plastic, ceramic, quartz, stainless steel, aluminum, and combinations thereof. The housing 126 may include one or more openings 128 so that electrical connectors 130 (connecting an electrical source to the transducer 120) can pass into the enclosed space 150. The transducer 120 may be positioned within an annular recess in an inner wall of the housing 126. The second surface 119 of the transmitter 122 remains exposed so that when the transducer assembly 300 is positioned above a substrate 50 (shown in FIG. 2), at least a portion of the second surface 119 may be coupled with a cleaning liquid 110 (shown in FIG. 2). The transducer assembly 300 may be used in conjunction with a variety of cleaning systems. An example of a single wafer cleaning system incorporating transducer assembly 300 is shown in FIG. 2.

Referring now to FIG. 2, megasonic cleaning system 100 comprises transducer assembly 300, a rotary support 104 and a liquid dispenser 106. In some embodiments the megasonic cleaning system 100 comprises a process chamber having a processing tank.

The rotary support 104 is positioned within a process chamber and is adapted to support a substrate 50. The rotary support 104 supports the substrate 50 in a generally horizontal orientation. Preferably, the rotary support 104 engages only the perimeter of the substrate 50 in performing its support function. In one embodiment, the substrate 50 is a semiconductor wafer. Preferably, the semiconductor wafer is positioned so that its device side is facing upward. However, other orientations are possible.

The rotary support 104 is operably coupled to a motor to facilitate rotation of the substrate within the horizontal plane of support. In one embodiment, the rotary support 104 comprises an outer rim 112 for engaging the substrate. The rim 112 can be supported by a plurality of spokes 201 that are connected to a hub 114, which is supported on a shaft 116. The motor is preferably a variable speed motor that can rotate the support 104 at any desired rotational speed.

To loosen particles on the substrate 50 surface, the transducer assembly 300 is configured to propagate megasonic energy to the surface of the substrate 50 by way of a meniscus of cleaning liquid 110 extending between the transmitter 122 and the substrate 50. The transducer assembly 300 must be positioned close enough to the substrate 50 surface so that a meniscus of liquid 110 extends between the transmitter 122 and the surface of the substrate 50. Preferably this distance is about one-tenth of an inch, or about 2.5 millimeters, creating a meniscus of the same height. The liquid forming the meniscus 110 may be applied to the surface of the substrate 50 by a dispenser 106.

The dispenser 106 or spray can be mounted within or operably connected to the wall of a process chamber or bowl. The dispenser 106 can be connected to gas and/or liquid supply lines (not shown) which can provide a cleaning liquid to the surface of the substrate 50 to be cleaned. The dispenser 106 preferably supplies cleaning liquid to the surface of the substrate 50 while the substrate 50 is rotating so as to form a film or meniscus 110 of the cleaning liquid on the substrate. The film or meniscus 110 of cleaning liquid may be a liquid and/or a liquid-gas combination. The position of the dispenser 106 with respect to the other components of the system 100 can vary depending on the cleaning operation to be carried out and, in some embodiments, the point in time during the cleaning process.

In one embodiment, while the cleaning liquid 110 is supplied to the substrate 50 by the fluid dispenser 106, the motor rotates the rotary support 104 beneath the transducer assembly 300 so that the entire upper surface of the substrate 50 is sufficiently close to the oscillating transmitter 122 to remove particles from the surface of the substrate 50. The rotation speed will vary depending upon the size of the substrate 50. As might be expected, longer cleaning times produce cleaner substrates. However, shorter cleaning times increase throughput, thereby increasing productivity. The transducer assembly 102 is then positioned at a predetermined distance relative to the surface of the substrate 50. At this position, the process fluid is in contact with the substrate 50 and the exposed surface of the transmitter 122. An electrical signal is then applied to the transducer 120 through an electrical energy source, which excites the transducer 120.

When the transducer 120 is electrically excited, it vibrates at a high frequency. Preferably the transducer 120 is energized at megasonic frequencies with the desired wattage consistent with the thickness of the transmitter 122 and work to be performed. The vibration is transmitted through the transducer 120 and to the transmitter 122. The transmitter 122 then transmits the high frequency energy into the cleaning liquid 110 between at least a portion of the second surface of the transmitter 122 and the substrate 50. Sufficient liquid between the transmitter 122 and the substrate 50 effectively transmits the energy across the small gap between the transmitter 122 and the substrate 50 to produce the desired cleaning. As each area of the substrate 50 approaches and passes the transmitter 122, the agitation of the liquid 110 between the transmitter 122 and the substrate 50 loosens particles on the substrate 50. Contaminants are thus vibrated away from the substrate 50 surface. The loosened particles may be carried away by a continuous fluid flow.

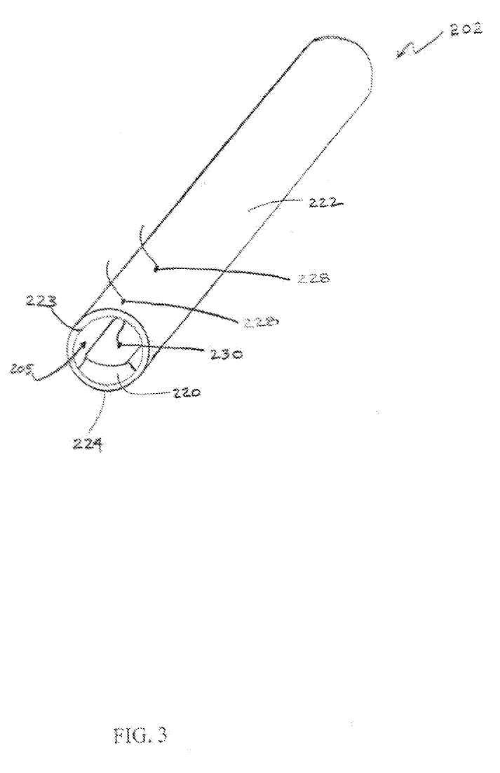

In another aspect, the invention is a novel transducer assembly 202, illustrated in FIG. 3. The transducer assembly 202 comprises a transducer 220 acoustically coupled to a tubular transmitter 222. The transducer 220 is made of piezoelectric crystal or ceramic. The transducer assembly 202 could comprise a plurality of transducers 220 acoustically coupled to the tubular transmitter 222.

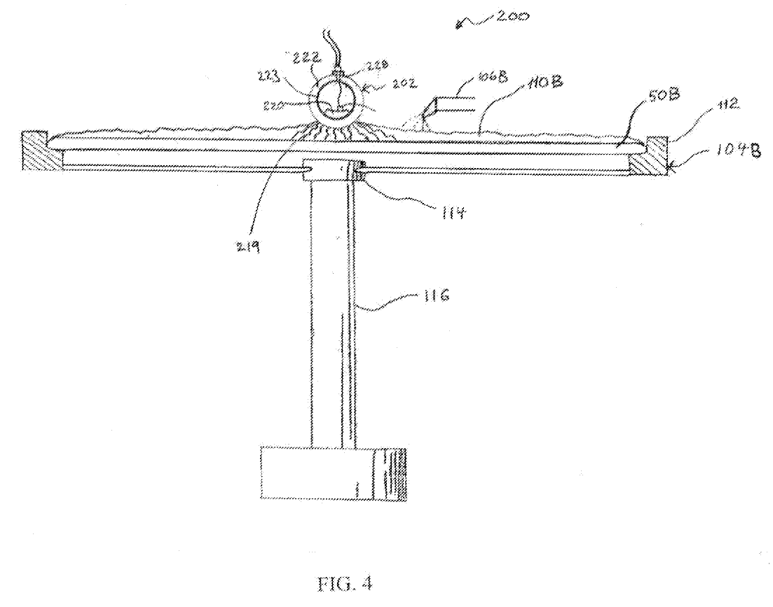

The tubular transmitter 222 comprises an inner surface 223 forming a cavity 205 and an outer elongate edge 224 (shown in FIG.4). At least one transducer 220 is bonded to the inner surface 223 of the tubular transmitter 222. The transducer 220 may be either directly bonded or indirectly bonded to the inner surface 223 of the tubular transmitter 222. The direct bonding may be in the same manner as discussed with respect to transducer assembly 300 (shown in FIG. 1). Alternatively, there may be one or more transmission layers (not shown) between the transducer 220 and the inner surface 223 of the tubular transmitter 222, thereby forming an indirect bond between the transducer 220 and the tubular transmitter 222.

At least one electrical connector 130B is connected to the transducer 220. The electrical connector 130B extends through one or more openings 228 into the cavity 205 of the tubular transmitter 222. The electrical connecter 130B is operably connected to a source of sonic energy (not shown) at another end.

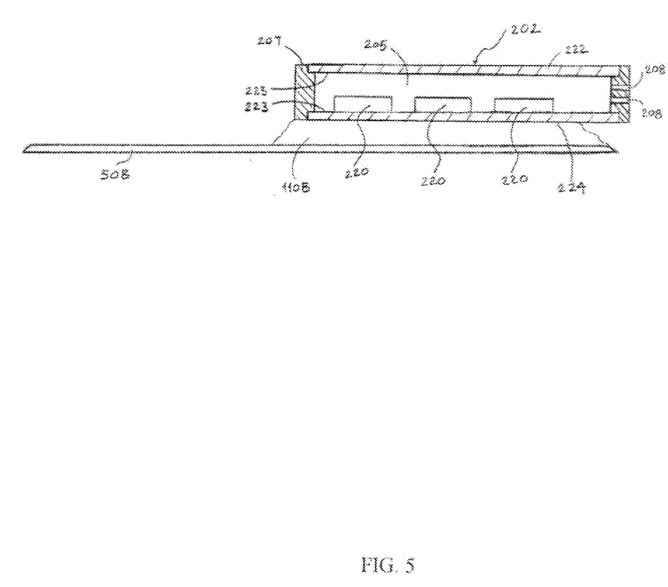

The transducer 220 may be made of crystal, ceramic or other material with piezoelectric properties. The transducer 220 may be rectangular in shape or it may be shaped so as to conform to portions of the tubular transmitter 222. The transducer 220 may have a length that extends the full length of the tubular transmitter 222. Alternatively, there may be a plurality of transducers 220 bonded in series to the inner surface 223 of the tubular transmitter 222 (shown in FIG. 5).

The tubular transmitter 222 may be cylindrical in shape. However, the tubular transmitter 222 is not limited in shape and can be any desired shape including, but not limited to, square, rectangular, trapezoidal or triangular. The tubular transmitter is a unitary structure and may be comprised of quartz, sapphire, an inert non-reactive plastic, boron nitride or vitreous carbide. The tubular transmitter 222 has a thickness selected by using a variety of factors, preferably, effectuating transmitting acoustic energy efficiently without losses and heat buildup, yet providing structural chemical stability and resistance for the process. The thickness of tubular transmitter 222 is preferably proportional to the frequency and amplitude of the electrical signal being transmitted through the transducer 220.

The transducer assembly 202 may be used in conjunction with a variety of cleaning systems. An example of a single wafer cleaning system incorporating transducer assembly 220 is shown in FIG. 4.

Referring now to FIG. 4, the megasonic cleaning system 200 comprises transducer assembly 202 and rotary support 104B. The structural components (and their functioning) of the megasonic cleaning system 200 are substantially similar to those discussed above with respect to the megasonic cleaning system 100. Therefore, in order to avoid redundancy, only those design aspects of the megasonic cleaning system 200 that substantially differ from the megasonic cleaning system 100 will be discussed.

The transducer assembly 202 is configured to propagate acoustic energy 219 to the surface of a substrate 50B by way of a meniscus of cleaning fluid 110B extending between the tubular transmitter 222 and the substrate 50B to loosen particles on the substrate 50B surface. The transducer assembly 202 must be positioned close enough to substrate 50B so that a meniscus of cleaning fluid 110B extends between the tubular transmitter 222 and the substrate 50B surface. The liquid forming the meniscus 110B may be applied to the surface of the substrate 50B by a suitable dispenser 106B.

Upon an electrical signal being received by the transducer 220, the electrical signal is converted into sonic energy 219 corresponding to the frequency and amplitude of the electrical signal. Once created, the sonic energy 219 can be transmitted through the elongate edge 224 (shown in FIG. 5) of the tubular transmitter 222 to the meniscus of liquid 110B. The sonic energy 219 is being directed at an angle to the surface of substrate 50B. The angle of the sonic energy 219 may be varied to improve the cleaning of substrates.

Referring now to FIG. 5, a side view of the transducer assembly 202 in cross-section and positioned above substrate 50B is shown. The tubular transmitter 222 is positioned horizontally and generally parallel to the substrate 50B surface. A plurality of crystals or ceramic transducers 220 are bonded to the inner surface 223 of the tubular transmitter 222. The invention is not so limited, however, and the transducer assembly 202 could comprise a single crystal or ceramic 220 bonded to the tubular transmitter 222.

Transducer assembly 202 may further comprise two ends walls 207. Each end wall 207 is positioned at an end of the tubular transmitter 222, thereby substantially enclosing the cavity 205. In one embodiment, the end walls 207 are formed by caps, however the invention is not so limited. Transducer assembly 202 may include two openings 208 adapted for flowing a gas into and out of the cavity 205 of the tubular transmitter 222 to provide cooling and purging.

The tubular transmitter 222 has a length at least equal to the length from an outer edge of the substrate 50B to the axis of rotation of the substrate 50B. This so that when the substrate 50B is rotated under the transducer assembly 202, the entire surface of the substrate 50B will pass under the transducer assembly 202 for cleaning.

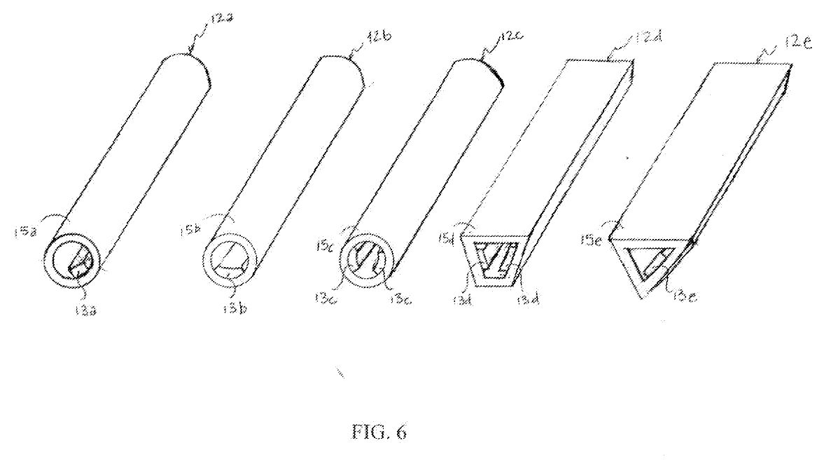

FIG. 6, shows five alternative embodiments of the transducer assembly. Transducer assembly 12a has a cylindrical shaped tubular transmitter 15a and a transducer 13a that is rectangular in shape. Transducer assembly 12b has a cylindrical shaped tubular transmitter 15b and a transducer 13b that is shaped so as to conform to a portion of the cylindrically shaped tubular transmitter 15b. Transducer assembly 12c has a cylindrically shaped tubular transmitter 15c and two transmitters 13c that are shaped so as to conform to portions of the tubular transmitter 15c. Transducer assembly 12d has a tubular transmitter 15d with a vertical cross sectional profile shaped as a trapezoid and transducers 13d that are rectangular in shape. Transducer assembly 12e has a tubular transmitter 15e with a vertical cross sectional profile shaped as a triangle and a transducer 13e that is rectangular in shape.

Whereas the present invention has been described in detail herein, it should be understood that other and further modifications, apart from those shown or suggested herein, may be made within the spirit and scope of the present invention. It is also intended that all matter contained in the foregoing description or shown in any accompanying drawings shall be interpreted as illustrative rather than limiting.

What is claimed is:

1. A transducer assembly for processing substrates comprising:
a crystal or ceramic adapted to convert electrical energy into sonic energy, the crystal or ceramic having a first conductive surface; and
a transmitter made of an inert non-reactive plastic for transmitting sonic energy generated by the crystal or ceramic, the transmitter having a first surface bonded directly to the first conductive surface of the crystal or ceramic.

2. The transducer assembly of claim 1 wherein the inert non-reactive plastic is a fluoropolymer.

3. The transducer assembly of claim 2 wherein the non-reactive plastic is selected from a group consisting of PTFE, PVDF, ETFE, TFE, FEP and PFA.

4. The transducer assembly of claim 1 wherein the inert non-reactive plastic is polypropylene, polyethylene, polyvinylchloride or polyimide.

5. The transducer assembly of claim 1 wherein the first surface of the transmitter is chemically and/or mechanically altered to increase cohesion between the first surface of the transmitter and the first conductive surface of the crystal or ceramic.

6. The transducer assembly of claim 1 wherein the first surface of the transmitter is etched to increase cohesion between the first surface of the transmitter and the first conductive surface of the crystal or ceramic.

7. The transducer assembly of claim 6 wherein the first surface of the transmitter is etched with a gaseous plasma or a liquid-based solution.

8. The transducer assembly of claim 1 wherein the inert non-reactive plastic is a fluoropolymer and the first surface of the transmitter is etched so that fluorine atoms on the first surface of the transmitter are replaced with a functional group.

9. The transducer assembly of claim 8 wherein the functional group is selected from a group consisting of a hydroxyl functional group, a carbonyl functional group, and a carboxyl functional group.

10. The transducer assembly of claim 1 wherein the first surface of the transmitter is mechanically roughened to increase cohesion between the first surface of the transmitter and the first conductive surface of the crystal or ceramic.

11. The transducer assembly of claim 1 further comprising an adhesive bonding the first surface of the transmitter directly to the first conductive surface of the crystal or ceramic.

12. The transducer assembly of claim 11 wherein the adhesive is selected from a group consisting of epoxy and cyanoacrylate-based adhesives.

13. The transducer assembly of claim 11 wherein the adhesive is sufficiently thin so that the adhesive does not substantially affect transmission of the sonic energy from the crystal or ceramic to the transmitter.

14. The transducer assembly of claim 13 wherein the adhesive has a thickness in a range between about 0.003 inches to about 0.007 inches.

15. The transducer assembly of claim 1 wherein the transmitter further comprises a second surface for coupling to a substrate process fluid, the sonic energy created by the crystal or ceramic being transmitted from the first surface of the transmitter to the second surface.

16. The transducer assembly of claim 1 wherein the first conductive surface of the crystal or ceramic is a metal coating or a conductive adhesive.

17. The transducer assembly of claim 1 wherein the inert non-reactive plastic is selected from a group consisting of PVDF, PFA, FEP, ETFE, PTFE, PP, PE, HPE, PVC and PI.

18. The transducer assembly of claim 1 comprising a plurality of the ceramic or crystals bonded to the transmitter.

19. The transducer assembly of claim 1 further comprising:
an adhesive that bonds the first surface of the transmitter to the first conductive surface of the crystal or ceramic, the adhesive having a thickness that does not substantially affect transmission of the sonic energy from the crystal or ceramic to the transmitter;
wherein the inert non-reactive plastic is selected from a group consisting of PVDF, PFA, FEP, ETFE, PTFE and TFE;
wherein the first surface of the transmitter is etched so that fluorine atoms on the first surface of the transmitter are replaced with a functional group; and
wherein the transmitter further comprises a second surface for coupling to a substrate process fluid, the sonic energy created by the crystal or ceramic being transmitted from the first surface of the transmitter to the second surface.

20. The transducer assembly of claim 1 further comprising an electrical energy source operably coupled to the ceramic or crystal.

21. The transducer assembly of claim 20 wherein the electrical energy source is adapted to supply electricity to the crystal or ceramic at a megasonic frequency.

22. The transducer assembly of claim 1 wherein the transmitter has a thickness in a range between about 0.02 inches to about 0.3 inches.

23. The transducer assembly of claim 22 wherein the transmitter has a thickness in a range between about 0.03 inches to about 0.08 inches.

24. The transducer assembly of claim 1 wherein the transmitter is a structure separate from a tank wall or tank floor.

25. The transducer assembly of claim 1 wherein the first surface of the transmitter is thermally fused to the first conductive surface of the crystal or ceramic.

26. A system for processing a substrate comprising:
means for supporting at least one substrate;
means for supplying a process fluid to the at least one substrate; and
a transducer assembly comprising a crystal or ceramic adapted to convert electrical energy into sonic energy, the crystal or ceramic having a first conductive surface, and a transmitter made of an inert non-reactive plastic for transmitting sonic energy generated by the crystal or ceramic, the transmitter having a first surface bonded directly to the first conductive surface of the crystal or ceramic and a second surface in contact with the process fluid.

27. The system of claim 26 wherein the support means is a rotatable support that supports a substrate in a substantially horizontal orientation, and wherein the process fluid supply means applies a film of process fluid to a surface of a substrate on the rotary support, the transducer assembly positioned so that at least a portion of the second surface of the transmitter is in contact with the film of the process fluid.

28. A method for processing a substrate comprising:
a) supporting a substrate;
b) contacting a first surface of a substrate with a process fluid;
c) providing a transducer assembly comprising a crystal or ceramic adapted to convert electrical energy into sonic energy, the crystal or ceramic having a first conductive surface, and a transmitter made of an inert non-reactive plastic for transmitting sonic energy generated by the crystal or ceramic, the transmitter having a first surface bonded directly to the first conductive surface of the crystal or ceramic and a second surface;
d) positioning the transducer assembly so that at least a portion of the second surface of the transmitter is in contact with the process fluid; and
e) applying an electrical signal to the crystal or ceramic so that sonic energy is created by the crystal or ceramic and transmitted by the transmitter into the process fluid and to the first surface of the substrate.
